(19) United States
(12) Patent Application Publication
(10) Pub. No.: US 2025/0311488 A1
(43) Pub. Date: Oct. 2, 2025

(54) OPTOELECTRONIC SEMICONDUCTOR DEVICE AND MANUFACTURING METHOD

(71) Applicant: ams-OSRAM International GmbH, Regensburg (DE)

(72) Inventors: Anna Kasprzak-Zablocka, Donaustauf (DE); Martin Hetzl, Painten (DE); Tansen Varghese, Regenburg (DE)

(21) Appl. No.: 18/864,823

(22) PCT Filed: May 3, 2023
(86) PCT No.: PCT/EP2023/061687

§ 371 Date: Nov. 11, 2024

(30) Foreign Application Priority Data
May 17, 2022 (DE) 10 2022 112 344.8

(51) Int. Cl. H10H 20/819; H10H 20/01; H10H 20/824

(52) U.S. Cl. CPC H10H 20/819; H10H 20/013; H10H 20/824

(57) ABSTRACT

In an embodiment an optoelectronic semiconductor device includes at least one semiconductor layer stack having an active region and one or more side surfaces, wherein the active region extends to the one or more side surfaces and a regrowth semiconductor layer covering the active region at the one or more side surfaces, wherein the at least one semiconductor layer stack is free of etching traces at the one or more side surfaces.

### CROSS-REFERENCE TO RELATED APPLICATIONS

This patent application is a national phase filing under section 371 of PCT/EP2023/061687, filed May 3, 2023, which claims the priority of German patent application 102022112344.8, filed May 17, 2022, each of which is incorporated herein by reference in its entirety.

### TECHNICAL FIELD

An optoelectronic semiconductor device and a manufacturing method for producing such an optoelectronic semiconductor device are specified. For example, the optoelectronic semiconductor device is suited for emitting electromagnetic radiation, in particular in the infrared, visible or ultraviolet spectral range.

### BACKGROUND

In an exemplary method for producing an optoelectronic semiconductor device, a semiconductor layer stack of the optoelectronic semiconductor device may be produced by patterning a semiconductor layer sequence by means of an etching process. In this context, the problem can arise that some layers of the semiconductor layer sequence having a heterostructure are etched with different etch rates and thus undergo underetching, which leads to steps between layers of different material compositions at side surfaces of the semiconductor layer stack. However, for a subsequent layer applied to the side surfaces of the semiconductor layer stack, it is crucial that a slope of the semiconductor layer stack is rather smooth. Especially if the subsequent layer is grown on the side surfaces, a smooth slope is important. Otherwise, it can have a lot of defects, which decrease device efficiency.

### SUMMARY

Embodiments provide an optoelectronic semiconductor device with improved efficiency.

Further embodiments provide a manufacturing method for producing an optoelectronic semiconductor device with improved efficiency.

According to at least one embodiment of an optoelectronic semiconductor device, it comprises at least one semiconductor layer stack including an active region. The active region may be provided for generating and emitting electromagnetic radiation. For example, the optoelectronic semiconductor device is suitable for emitting electromagnetic radiation having a wavelength in the infrared, visible or ultraviolet spectral range.

Moreover, the semiconductor layer stack may comprise one or more side surfaces. Dependent on the geometry of the semiconductor layer stack, it has one side surface, for example if cylindrical, or several side surfaces, for example if polyhedral. The one or more side surfaces delimit the semiconductor layer stack in lateral directions.

Furthermore, the active region may extend to the one or more side surfaces. In other words, a side surface or side surfaces of the active region may form a part of the one or more side surfaces of the semiconductor layer stack.

According to at least one embodiment, the optoelectronic semiconductor device comprises a regrowth semiconductor layer covering the active region at the one or more side surfaces. In other words, the regrowth semiconductor layer may be arranged on the one or more side surfaces of the semiconductor layer stack such that it covers the active region or side surfaces of the active region. By means of the regrowth semiconductor layer covering the active region, the number of traps at the one or more side surfaces can be reduced and thus radiation efficiency of the active region can be improved.

According to at least one embodiment, the at least one semiconductor layer stack is free of etching traces at the one or more side surfaces. Etching traces are recognizable in the surface structure of the semiconductor layer stack, for example in the form of steps between layers of different material compositions at side surfaces of the semiconductor layer stacks. A manufacturing method presented here does not require any direct etching process for structuring the semiconductor layer stack, and thus the semiconductor layer stack may have a rather smooth slope and fewer defects occur in the regrowth semiconductor layer than in the case of an etching process.

According to at least one embodiment of an optoelectronic semiconductor device, it comprises:
at least one semiconductor layer stack including an active region and having one or more side surfaces, wherein the active region extends to the one or more side surfaces,
a regrowth semiconductor layer covering the active region at the one or more side surfaces, wherein
the at least one semiconductor layer stack is free of etching traces at the one or more side surfaces.

According to at least one embodiment or configuration, the regrowth semiconductor layer is applied directly on the semiconductor layer stack. Hence, the regrowth semiconductor layer and the semiconductor layer stack may touch each other.

According to at least one embodiment or configuration, the regrowth semiconductor layer covers every side surface at least for the most part. In other words, the semiconductor layer stack may be laterally surrounded at least for the most part by the regrowth semiconductor layer.

According to at least one embodiment or configuration, the regrowth semiconductor layer extends from the one or more side surfaces to a main surface of the at least one semiconductor layer stack. In other words, the regrowth semiconductor layer may also cover the main surface. The main surface may be arranged obliquely to every side surface. For example, the main surface may delimit the semiconductor layer stack in a vertical direction, wherein the vertical direction runs perpendicularly to the lateral directions. For example, the vertical direction is the direction in which semiconductor layers of the semiconductor layer sequence follow one another.

According to at least one embodiment or configuration, the regrowth semiconductor layer comprises an opening at the main surface. Hence, the regrowth semiconductor layer partly covers the main surface. An electric contact layer may be arranged in the opening and may electrically contact the at least one semiconductor layer stack. The electric contact layer may comprise a metallic layer and/or a layer of a transparent conductive oxide, like ITO. Alternatively, the regrowth semiconductor layer may be formed without any opening at the main surface. And the electric contact layer may electrically contact the regrowth semiconductor layer in this case.

According to at least one embodiment or configuration, a semiconductor material system of the semiconductor layer stack and/or the regrowth semiconductor layer is InGaAlP or AlInGaAsP. However, it is also possible that the semiconductor layer stack and/or the regrowth semiconductor layer are based on an AlInGaN material system or on an AlInGaAs material system. For example, in the case of an InGaAlP or AlInGasAsP material system, the regrowth semiconductor layer may comprise an undoped InGaAlP layer or a p-doped InAlP layer. Moreover, in the case of an AlInGaN material system, the regrowth semiconductor layer may comprise an undoped InGaAlN layer or a p-doped InGaAlN layer. Especially, the semiconductor layer stack and the regrowth semiconductor layer are based on the same semiconductor material system.

According to at least one embodiment or configuration, the semiconductor layer stack comprises a first semiconductor region of a first conductivity type, for example a p-doped semiconductor region, and a second semiconductor region of a second conductivity type, for example an n-doped semiconductor region.

The active region may be arranged between the first and second semiconductor regions. The active region may comprise a sequence of single layers which form a quantum well structure, in particular a single quantum well (SQW) structure or multiple quantum well (MQW) structure.

Moreover, the first and second semiconductor regions may each have a sequence of single layers, some of which may be undoped or lightly doped. The single layers of the semiconductor regions may be epitaxially deposited on a patterned growth substrate.

Moreover, the regrowth semiconductor layer may be single layer and can be made of a single material homogeneously distributed all across the regrowth semiconductor layer. But it is also possible that the regrowth semiconductor layer is a multi-layer and comprises two or more sub-layers. Adjacent sub-layers or all the sub-layers may differ from each other in a material composition and/or in a doping concentration and/or in a doping type.

According to at least one embodiment or configuration, the at least one semiconductor layer stack has a cross section similar to an acute trapezoid, wherein values of each acute angle range between 15° and 60°. The manufacturing method presented here, which does not require any direct etching process, allows for selecting the angles rather freely.

According to at least one embodiment or configuration, the optoelectronic semiconductor device comprises a plurality of semiconductor layer stacks as described above, wherein every semiconductor layer stack includes an active region and has one or more side surfaces. The semiconductor layer stacks may be arranged on a common carrier. Especially, the optoelectronic semiconductor device comprises a regrowth semiconductor layer covering every active region at the one or more side surfaces of the semiconductor layer stacks.

According to at least one embodiment or configuration, the optoelectronic semiconductor device is a MicroLed also known for example as micro-LED, μLED, μ-LED, uLED, u-LED or micro light emitting diode. In this embodiment or configuration, the optoelectronic semiconductor device has a particularly small size.

The method described below is suitable for the production of an optoelectronic semiconductor device described here. The features described in connection with the optoelectronic semiconductor device can therefore also apply to the method, and vice versa.

According to at least one embodiment of a manufacturing method for producing an optoelectronic semiconductor device as described above, the method comprises the following steps, preferably in the stated order:
providing a patterned growth substrate comprising at least one opening,
growing, especially epitaxially growing, a semiconductor layer sequence on the patterned growth substrate such that the semiconductor layer sequence is arranged in the at least one opening, wherein the semiconductor layer sequence in the at least one opening forms a semiconductor layer stack including an active region and having one or more side surfaces,
removing parts of the patterned growth substrate which cover the one or more side surfaces of the at least one semiconductor layer stack,
depositing, especially epitaxially growing, a regrowth semiconductor layer on the one or more side surfaces of the at least one semiconductor layer stack, wherein the regrowth semiconductor layer covers the active region at the one or more side surfaces.

Due to the growth in the at least one opening, the semiconductor layer stack formed therein essentially, that is within common production tolerances, has the same three-dimensional shape as the at least one opening. And the semiconductor layer stack can be grown with a desired three-dimensional shape. Hence, there is no need for patterning the semiconductor layer sequence, for example by an etching process, in order to create a semiconductor layer stack having a desired three-dimensional shape. And thus, the at least one semiconductor layer stack can be produced without etching traces at the one or more side surfaces. For example, the three-dimensional shape of the semiconductor layer stack and the opening may be a truncated cone or a truncated pyramid.

According to at least one embodiment or configuration, the at least one semiconductor layer stack is formed with a height lower than a depth of the at least one opening. This leads to portions of the patterned growth substrate which project beyond a main surface of the at least one semiconductor layer stack facing away from a bottom of the opening. The portions projecting beyond the main surface facilitate the removal of parts of the patterned growth substrate. For example, a height of the at least one semiconductor layer stack is at least 0.2 μm and at most 10 μm. The height and depth may be determined along the vertical direction.

According to at least one embodiment or configuration, the step of removing parts of the patterned growth substrate includes an etching process. The step of removing parts of the patterned growth substrate may be preceded by a step of removing the semiconductor layer sequence on the parts to be removed by chemical mechanical polishing, for example.

According to at least one embodiment or configuration, the step of providing a patterned growth substrate includes providing a growth substrate layer and removing material from the growth substrate layer to form the at least one opening of the patterned growth substrate, wherein the growth substrate layer comprises a semiconductor material. For example, the growth substrate layer may comprise or consist of GaAs. For example, the growth substrate layer may be patterned by lithography using a resist mask and an etching process, for example a wet chemical etching process.

Alternatively, the step of providing a patterned growth substrate may include providing a growth substrate layer, which comprises or consists of a semiconductor material, for example GaAs, and forming a patterned layer on the growth substrate layer, wherein the patterned layer comprises the at least one opening of the patterned growth substrate.

According to at least one configuration, the step of forming the patterned layer may include:
providing a resist mask on the growth substrate layer in areas where the at least one opening is to be formed,
depositing material of the patterned layer on the growth substrate layer around the resist mask, and
removing the resist mask, wherein the at least one opening is formed. The patterned layer may comprise a dielectric material, for example Al2O3.

The step of depositing material of the patterned layer on the growth substrate layer may include a sputtering process or any low temperature process which does not lead to a damage of the resist mask.

Moreover, the step of removing the resist mask may be preceded by a step of removing the material of the patterned layer on an upper surface of the resist mask facing away from the growth substrate layer, for example by chemical mechanical polishing or dry etching, and then removing the resist mask, for example by a solvent.

Alternatively, the step of forming the patterned layer may include:
providing a resist mask on the growth substrate layer in areas where the patterned layer is to be formed,
depositing a dielectric material, for example SiO2, on the growth substrate layer around the resist mask,
removing the resist mask,
depositing material of the patterned layer on the growth substrate layer in areas where the resist mask has been removed, and
removing the dielectric material, wherein the at least one opening is formed. For example, the patterned layer may comprise a semiconductor material like GaAs. The patterned layer may be grown, especially epitaxially grown, on the growth substrate layer.

The step of depositing the dielectric material on the growth substrate layer may include a sputtering process or any low temperature process which does not lead to a damage of the resist mask.

Moreover, the step of removing the resist mask may be preceded by a step of removing the dielectric material on the upper surface of the resist mask together with the resist mask by a lift-off technique or by chemical mechanical polishing and resist stripping.

Furthermore, the step of removing the dielectric material to create the at least one opening may include an etching process.

In the embodiments described, the step of providing a resist mask may include applying a resist layer on the growth substrate layer and patterning the resist layer by lithography.

The optoelectronic semiconductor device presented here may be a MicroLed and is suitable for AR (augmented reality), VR (virtual reality) and display applications. The MicroLed or a plurality of microLeds may form pixels or subpixels of a display device and emit light of a defined color. Small pixel size and a high density with close distances make the microLed(s) suitable, among others, for small monolithic displays for AR applications, especially data glasses. Moreover, the MicroLed(s) may be used for communication and lighting applications.

### BRIEF DESCRIPTION OF THE DRAWINGS

Further preferred embodiments and further developments of the optoelectronic semiconductor device and the manufacturing method for producing the optoelectronic semiconductor device will become apparent from the exemplary embodiments explained below in conjunction with FIGS. 1 to 9.

FIG. 1 shows a schematic cross-sectional view of an exemplary embodiment of an optoelectronic semiconductor device;

FIG. 2 shows a schematic cross-sectional view of a comparative example of an optoelectronic semiconductor device;

FIGS. 3A to 3F show schematic cross-sectional views of method steps of a first exemplary embodiment of a manufacturing method for optoelectronic semiconductor devices described herein;

FIGS. 3A to 3C and 4A to 4C show schematic cross-sectional views of method steps of a second exemplary embodiment of a manufacturing method for optoelectronic semiconductor devices described herein;

FIGS. 5 to 7 show schematic cross-sectional views of patterned growth substrates according to different exemplary embodiments;

FIGS. 8A to 8H show schematic cross-sectional views of method steps of a third exemplary embodiment of a manufacturing method for optoelectronic semiconductor devices described herein; and

FIGS. 9A to 9I show schematic cross-sectional views of method steps of a forth exemplary embodiment of a manufacturing method for optoelectronic semiconductor devices described herein.

Identical, equivalent or equivalently acting elements may be indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION OF ILLUSTRATIVE EMBODIMENTS

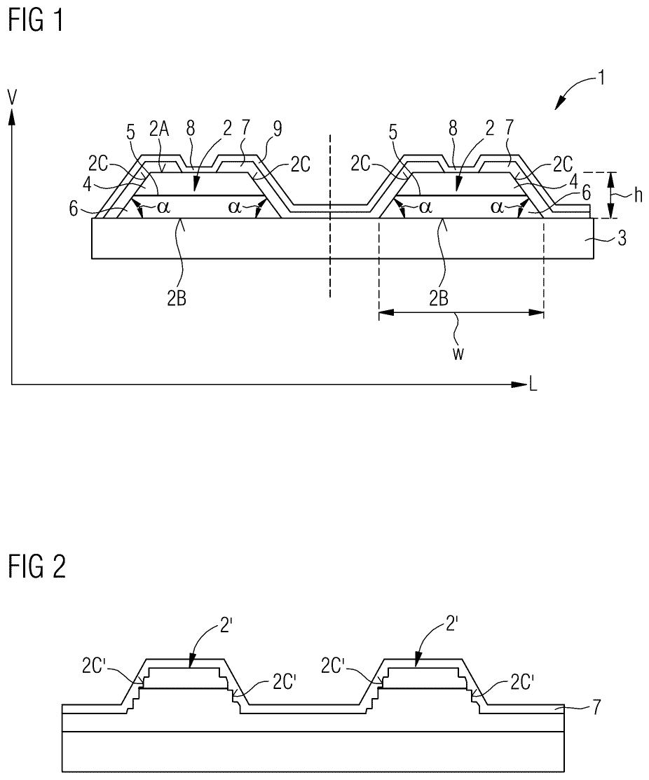

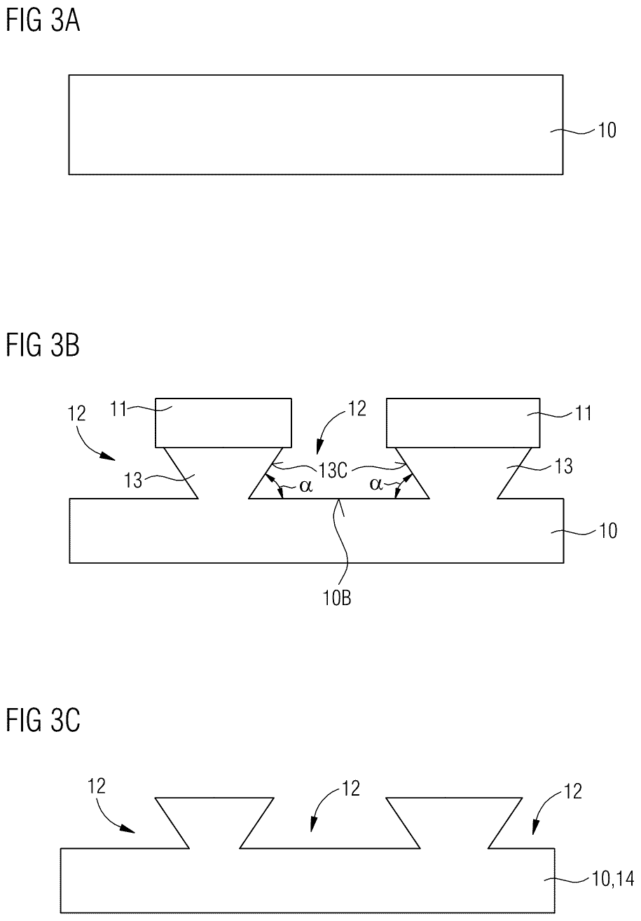

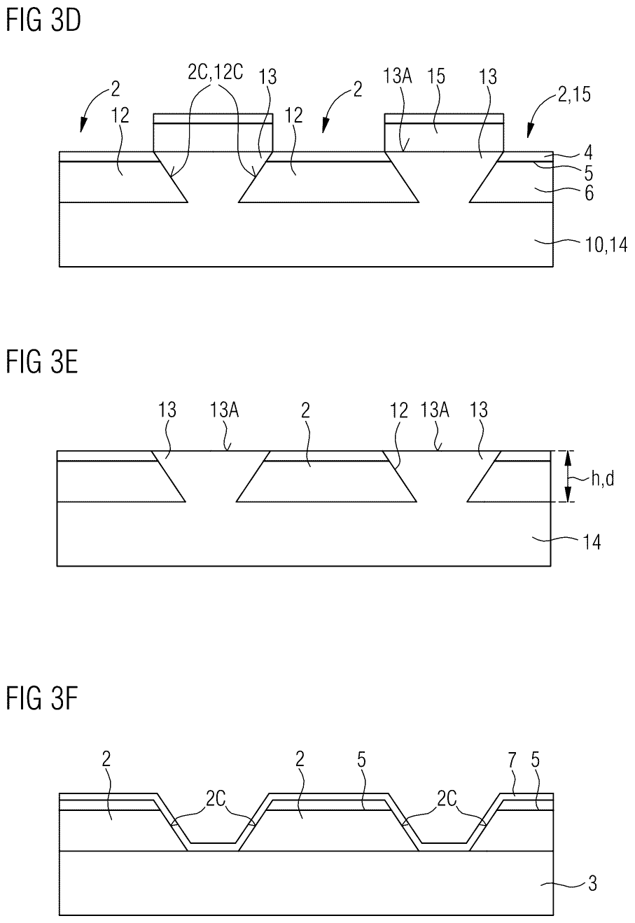

FIG. 1 illustrates an exemplary embodiment of an optoelectronic semiconductor device 1. The optoelectronic semiconductor device 1 comprises two or more semiconductor layer stacks 2. However, as indicated by a separation line, it is also possible that the optoelectronic semiconductor device 1 comprises only one semiconductor layer stack 2. The semiconductor layer stacks 2 are arranged on a common carrier 3, which may be a part of a patterned growth substrate 14 used for depositing a semiconductor layer sequence 15 in order to produce the semiconductor layer stacks 2 as described below in more detail (see FIGS. 3D to 3F, for example).

The semiconductor layer stacks 2 in each case include an active region 5, in particular for generating and emitting electromagnetic radiation. For example, the optoelectronic semiconductor device 1 is suitable for emitting electromagnetic radiation having a wavelength in the infrared, visible or ultraviolet spectral range.

Moreover, the semiconductor layer stacks 2 in each case comprise a first semiconductor region 4 of a first conductivity type, for example a p-doped semiconductor region, and a second semiconductor region 6 of a second conductivity type, for example an n-doped semiconductor region.

The active region 5 is arranged between the first and second semiconductor regions 4, 6 and may comprise a sequence of single layers which form a quantum well structure, in particular a single quantum well (SQW) structure or multiple quantum well (MQW) structure. Moreover, the first and second semiconductor regions 4, 6 may each have a sequence of single layers, some of which may be undoped or lightly doped (not shown).

The semiconductor layer stacks 2 in each case have a three-dimensional shape similar to a truncated pyramid and at least three, preferably at least four, side surfaces 2C, which delimit the respective semiconductor layer stack 2 in lateral directions L and run obliquely to a main extension plane of the carrier 3. The lateral directions L may be parallel to the main extension plane of the carrier 3. The semiconductor layer stacks 2 in each case have a cross section similar to an acute trapezoid, wherein values of each acute angle a range between 15° and 60°. The angle a is the angle between the respective side surface 2C and a second main surface 2B.

The active regions 5 in each case run essentially, that is within common production tolerances, parallel to the main extension plane of the carrier 3 and extend to the side surfaces 2C. In other words, side surfaces of the active regions 4 may in each case form a part of the side surfaces 2C of the semiconductor layer stacks 2.

The optoelectronic semiconductor device 1 further comprises a regrowth semiconductor layer 7 covering the active regions 5 at the side surfaces 2C of every semiconductor layer stack 2. In other words, the regrowth semiconductor layer 7 is arranged on the side surfaces 2C of every semiconductor layer stack 2 such that it covers the active regions 5 or the side surfaces of the active regions 5. Especially, the regrowth semiconductor layer 7 covers every side surface 2C at least for the most part such that the semiconductor layer stacks 2 in each case are laterally surrounded at least for the most part by the regrowth semiconductor layer 7. The regrowth semiconductor layer 7 may be applied directly on the semiconductor layer stacks 2 and thus touch the semiconductor layer stacks 2. Preferably, the regrowth semiconductor layer 7 is epitaxially grown on the semiconductor layer stacks 2.

By means of the regrowth semiconductor layer 7 covering the active regions 5, the number of traps at the side surfaces 2C can be reduced and thus radiation efficiency of the active regions 5 can be improved.

The regrowth semiconductor layer 7 extends in each case from the side surfaces 2C to a first main surface 2A of the semiconductor layer stacks 2, wherein the first main surface 2A in each case is arranged on a side opposite to the carrier 3 and obliquely to every side surface 2C. The main surface 2A in each case delimits the semiconductor layer stack 2 in a vertical direction V, wherein the vertical direction V runs perpendicularly to the lateral directions L. Moreover, the second main surface 2B in each case delimits the semiconductor layer stack 2 on a side facing the carrier 3.

The regrowth semiconductor layer 7 comprises an opening 8 at every first main surface 2A and hence partly covers the respective first main surface 2A. An electric contact layer 9 is arranged on a side of the regrowth semiconductor layer 7 facing away from the semiconductor layer stacks 2 and extends in the openings 8. The electric contact layer 9 in each case electrically contacts the semiconductor layer stacks 2. The electric contact layer 9 may comprise a metallic layer and/or a layer of a transparent conductive oxide, like ITO. Alternatively, the regrowth semiconductor layer 7 may be formed without any opening at the first main surface 2A. And the electric contact layer 9 may electrically contact the regrowth semiconductor layer 7 in this case.

A suitable semiconductor material system of the semiconductor layer stacks 2 and/or the regrowth semiconductor layer 7 is InGaAlP or AlInGaAsP. However, it is also possible that the semiconductor layer stacks 2 and/or the regrowth semiconductor layer 7 are based on an AlInGaN material system or on an AlInGaAs material system. For example, in the case of an InGaAlP or AlInGasAsP material system, the regrowth semiconductor layer 7 may comprise an undoped InGaAlP layer or a p-doped InAlP layer. Moreover, in the case of an AlInGaN material system, the regrowth semiconductor layer 7 may comprise an undoped InGaAlN layer or a p-doped InGaAlN layer. Especially, the semiconductor layer stacks 2 and the regrowth semiconductor layer 7 are based on the same semiconductor material system.

The regrowth semiconductor layer 7 may be a single layer and can be made of a single material homogeneously distributed all across the regrowth semiconductor layer 7. But it is also possible that the regrowth semiconductor layer 7 is a multi-layer and comprises two or more sub-layers (not shown). Adjacent sub-layers or all the sub-layers may differ from each other in a material composition and/or in a doping concentration and/or in a doping type.

A height h of the semiconductor layer stacks 2, that is a maximum extension along the vertical direction V, in each case may be at least 0.2 μm and at most 10 μm.

Moreover, a width w of the semiconductor layer stacks 2, that is a maximum extension along at least one lateral direction L, in each case may be at least 200 nm and at most 100 μm.

The optoelectronic semiconductor device 1 may be embodied as a MicroLed with a particularly small size including a maximum extension along the vertical direction V ranging from 1.5 μm to 10 μm, for example, and a maximum extension along the lateral direction(s) L less than or equal to 100 μm or less than or equal to 70 μm or less than or equal to 50 μm.

The semiconductor layer stacks 2 in each case are free of etching traces at the side surfaces 2C. Etching traces are recognizable in the surface structure of the semiconductor layer stacks 2, for example in the form of steps between layers of different material compositions at side surfaces 2C′ of the semiconductor layer stacks 2′ as becomes evident from FIG. 2.

The semiconductor layer stacks 2′ of the comparative example shown in FIG. 2 are produced, for example, by patterning a semiconductor layer sequence by means of an etching process, wherein some layers of the semiconductor layer sequence having a heterostructure are etched with different etch rates and thus undergo underetching, which leads to steps between layers of different material compositions at the side surfaces 2C′ of the semiconductor layer stacks 2′.

However, the semiconductor layer stacks 2 as shown in FIG. 1 in each case have a rather smooth slope, and thus fewer defects than in the case of an etching process occur in the regrowth semiconductor layer 7, which is applied on the side surfaces 2C of the semiconductor layer stacks 2. This results in an improved device efficiency.

In connection with FIGS. 3A to 3F, a first exemplary embodiment of a manufacturing method for producing an optoelectronic semiconductor device as described in connection with FIG. 1, for example, is explained in more detail.

Starting with FIG. 3A, the method comprises the step of providing a growth substrate layer 10, which comprises or consists of a semiconductor material like GaAs.

Continuing with FIG. 3B, the method further comprises the steps of providing a resist layer (not shown) on the growth substrate layer 10, patterning the resist layer by lithography and producing a resist mask 11. In a further step, the growth substrate layer 10 is patterned by the resist mask 11 using an etching process, for example a wet chemical etching process, and material is removed from the growth substrate layer 10 such that one or several openings 12 are produced in the growth substrate layer 10. The patterned growth substrate layer 10 comprises projecting portions 13, which laterally surround the openings 12, wherein angles a between side surfaces 13C of the projecting portions 13 and a respective bottom face 10B at a bottom of the openings 12 in each case are essentially, that is within common production tolerances, identical to the angles a between the side surfaces 2C and the second main surface 2B of the semiconductor layer stack/s 2 to be produced (see FIG. 1).

As shown in FIG. 3C, the resist mask 11 is removed after patterning the growth substrate layer 10. The patterned growth substrate layer 10 constitutes a patterned growth substrate 14 comprising at least one opening 12.

Continuing with FIG. 3D, the method further comprises the step of growing a semiconductor layer sequence 15 on the patterned growth substrate 14 such that the semiconductor layer sequence 15 is arranged in the openings 12, wherein the semiconductor layer sequence 15 in the openings 12 in each case forms a semiconductor layer stack 2 including an active region 5 and having one or more side surfaces 2C. The semiconductor layer sequence 15 is formed from the semiconductor material as mentioned above in connection with the semiconductor layer stacks 2.

In particular, the semiconductor layer sequence 15 is epitaxially grown on the patterned growth substrate 14. While parasitic growth occurs in each case on main surfaces 13A of the projecting portions 13, the growth conditions can be controlled in such a way that growth on edges of the main surfaces 13A is prevented.

Continuing with FIG. 3E, the method further comprises the step of removing the parasitic growth portions on the main surfaces 13A of the projecting portions 13 by chemical-mechanical polishing, for example. Here, the semiconductor layer stacks 2 are formed in each case with a height h similar to the height of the projecting portions 13 or a depth d of the openings 12.

Continuing with FIG. 3F, the method further comprises the step of removing parts of the patterned growth substrate 14, which cover the one or more side surfaces 2C of the semiconductor layer stacks 2. Especially, the projecting portions 13 are removed in this step. The removal process is an etching process, for example. After the removal process, the side surfaces 2C may undergo a cleaning process in order to reduce defects. The semiconductor layer stacks 2 produced in this way are arranged on a common carrier 3, which is a part of the patterned growth substrate 14, and are laterally spaced from each other by interspaces originating from the removed parts of the patterned growth substrate 14.

The method further comprises the step of depositing, especially epitaxially growing, a regrowth semiconductor layer 7 on the side surfaces 2C of the semiconductor layer stacks, wherein the regrowth semiconductor layer 7 in each case covers the active regions 5 at the side surfaces 2C.

The method may further comprise the step of producing an electric contact layer (not shown).

Due to the growth in the openings 12, the semiconductor layer stacks 2 formed therein in each case essentially, that is within common production tolerances, have the same three-dimensional shape as the openings 12. And the semiconductor layer stacks 2 can be grown with a desired three-dimensional shape. Hence, there is no need for patterning the semiconductor layer sequence 15, for example by an etching process, in order to create semiconductor layer stacks 2 having a desired three-dimensional shape. And thus, the semiconductor layer stacks 2 can be produced without etching traces at the side surfaces 2C providing for smoother slopes and thus for a better quality of the regrowth semiconductor layer 7. For example, the three-dimensional shape of the openings 12 may in each case be a truncated pyramid.

In addition, the method may have any of the features, characteristics and advantages mentioned in connection with the further exemplary embodiments.

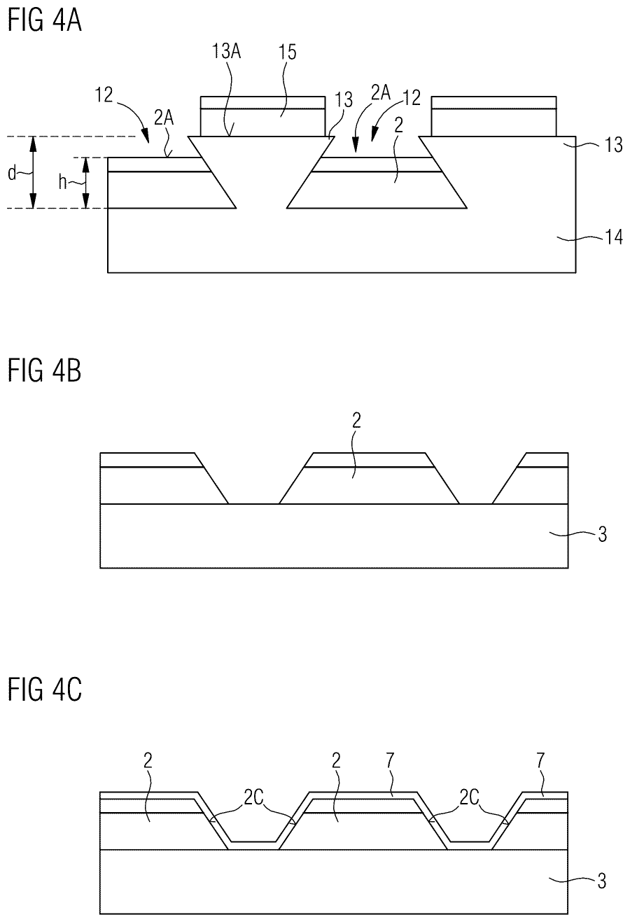

In connection with FIGS. 4A to 4C, a second exemplary embodiment of a manufacturing method for producing an optoelectronic semiconductor device as described in connection with FIG. 1, for example, is explained in more detail.

The method steps illustrated in FIGS. 4A to 4C may be preceded by the method steps described in connection with FIGS. 3A to 3C.

As illustrated in FIG. 4A, when growing the semiconductor layer sequence 15, the semiconductor layer stacks 2 in the openings 12 are formed with a height h lower than the depth d of the openings 12. This leads to projecting portions 13, which in each case project beyond the first main surfaces 2A of the semiconductor layer stacks 2.

The projecting portions 13, which are higher than the semiconductor layer stacks 2, are easier to remove. The parasitic growth portions of the semiconductor layer sequence 15 on the main surfaces 13A of the projecting portions 13 can be removed along with the projecting portions 13 or parts of the patterned growth substrate 14 by etching, for example (see FIG. 4B). Thus, the step of chemical-mechanical polishing can be omitted.

Subsequent steps of the manufacturing method (see FIG. 4C) can be conducted as described in connection with FIG. 3F.

In addition, the method may have any of the features, characteristics and advantages mentioned in connection with the further exemplary embodiments.

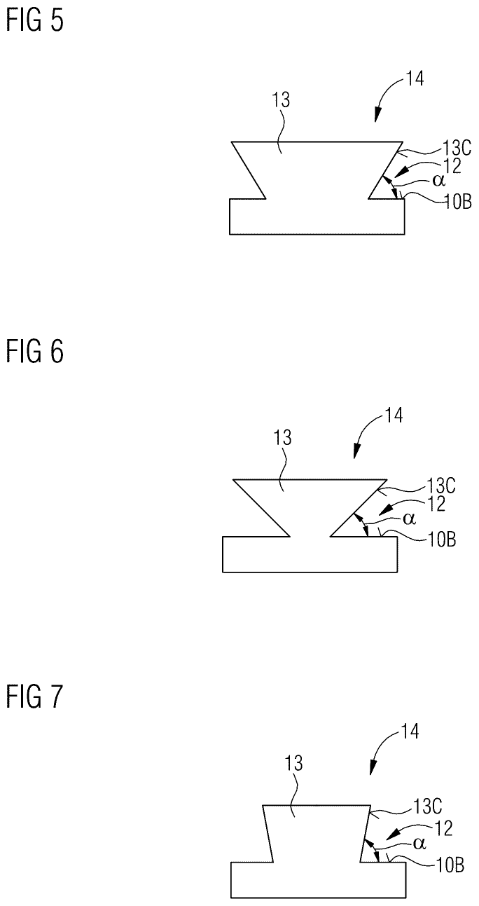

FIGS. 5 to 7 show different exemplary embodiments of the patterned growth substrate 14. As becomes evident from these Figures, the angle a between a side surface 13C of a projecting portion 13 and a bottom face 10B at the bottom of an opening 12 can be selected rather freely, for example between 0° and 90°, preferably between 15° and 60°, independent of the material of the semiconductor layer sequence and in a manner best suited for depositing the regrowth layer.

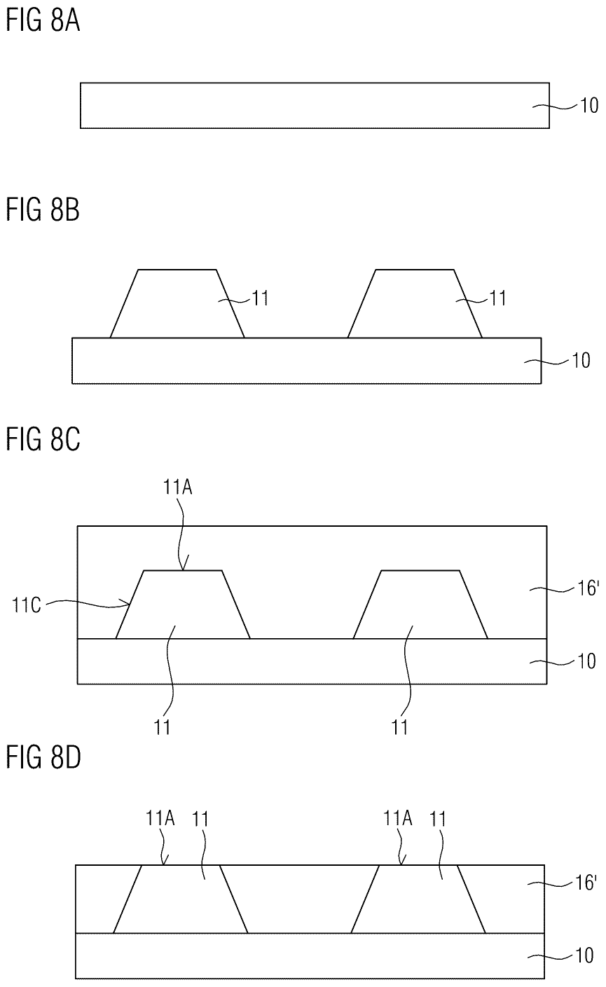

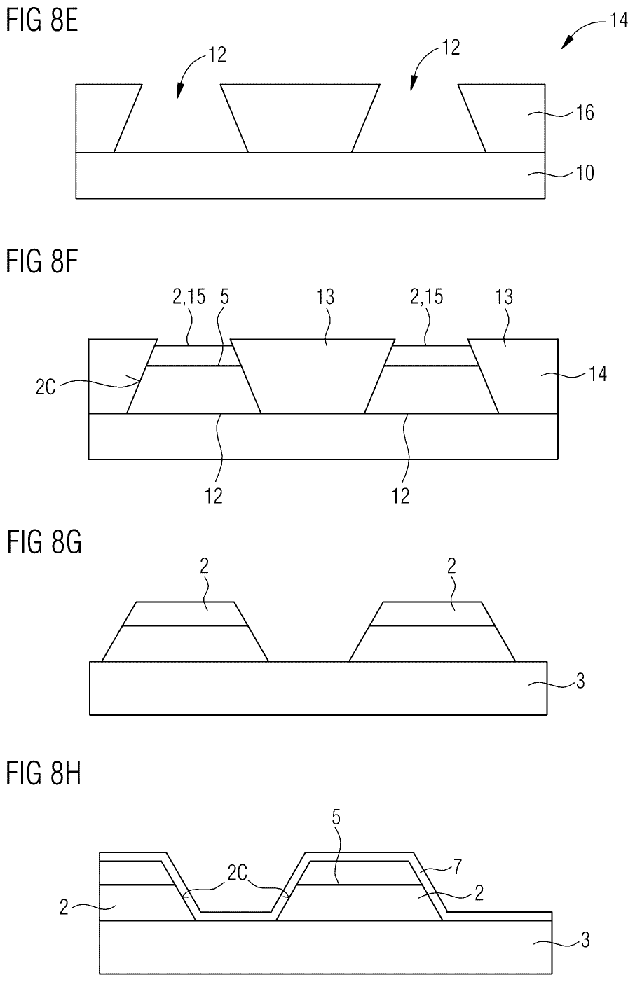

In connection with FIGS. 8A to 8H, a third exemplary embodiment of a manufacturing method for producing an optoelectronic semiconductor device as described in connection with FIG. 1, for example, is explained in more detail.

Starting with FIG. 8A, a growth substrate layer 10 is provided, which comprises or consists of a semiconductor material, for example GaAs.

Continuing with FIG. 8B, a resist mask 11 is provided on the growth substrate layer 10 in areas where openings 12 of the patterned growth substrate 14 (see FIG. 8E) are to be formed. A shape of the resist mask 11 can be tuned with lithography conditions.

Continuing with FIG. 8C, material 16′ of a patterned layer 16 (see FIG. 8E) is deposited on the growth substrate layer 10 around the resist mask 11. The material 16′ may cover upper and side surfaces 11A, 11C of the resist mask 11. The material 16′ of the patterned layer 16 may be a dielectric material, for example Al2O3. The material 16′ of the patterned layer 16 may be deposited by a sputtering process or any low temperature process which does not lead to a damage of the resist mask 11.

Continuing with FIG. 8D, the material 16′ of the patterned layer 16 on the upper surface 11A of the resist mask 11 facing away from the growth substrate layer 10 is removed by chemical mechanical polishing or dry etching, for example.

Continuing with FIG. 8E, the resist mask 11 is removed by a solvent, for example, and thus a patterned layer 16 is formed comprising openings 12. The growth substrate layer 10 with the patterned layer 16 constitutes a patterned growth substrate 14.

Continuing with FIG. 8F, a semiconductor layer sequence 15 is grown on the patterned growth substrate 14 such that the semiconductor layer sequence 15 is arranged in the openings 12, wherein the semiconductor layer sequence 15 in the openings 12 in each case forms a semiconductor layer stack 2 including an active region 5 and having one or more side surfaces 2C. The growth process can be an MOCVD (Metal-Organic Chemical Vapor Deposition) process. The semiconductor layer stacks 2 are at the most as high as the openings 12 are deep.

Continuing with FIG. 8G, parts of the patterned growth substrate 14 which cover the side surfaces 2C of the semiconductor layer stacks 2, are removed. Especially, the parts which are removed are projecting portions 13 of the patterned growth substrate 14 formed by the patterned layer 16. After the removal process, the side surfaces 2C may undergo a cleaning process in order to reduce defects. The semiconductor layer stacks 2 produced in this way are arranged on a common carrier 3, which is a part of the patterned growth substrate 14, and are laterally spaced from each other by interspaces originating from the removed parts of the patterned growth substrate 14.

Subsequent steps of the manufacturing method (see FIG. 8H) can be conducted as described in connection with FIG. 3F.

In addition, the method may have any of the features, characteristics and advantages mentioned in connection with the further exemplary embodiments.

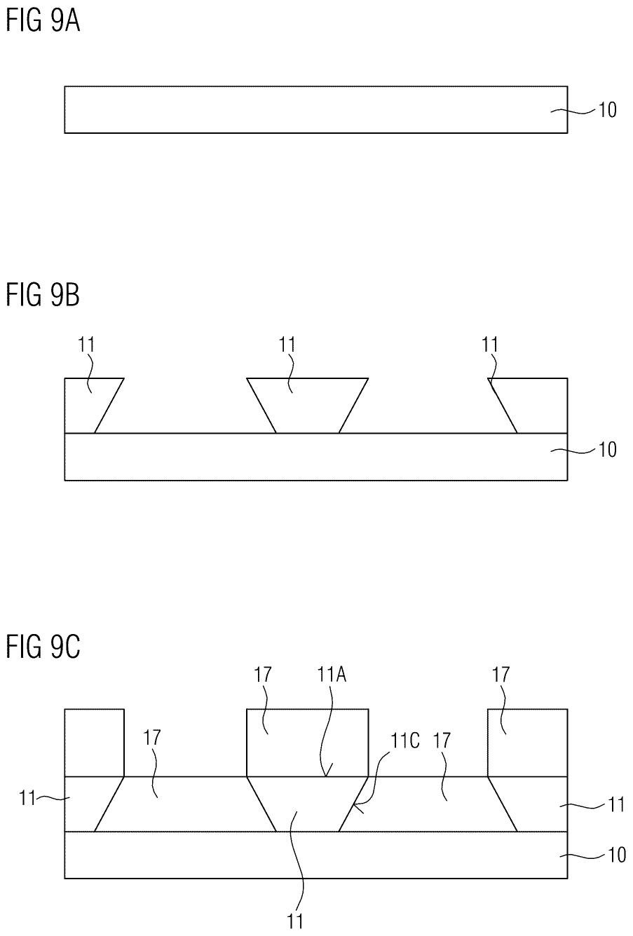

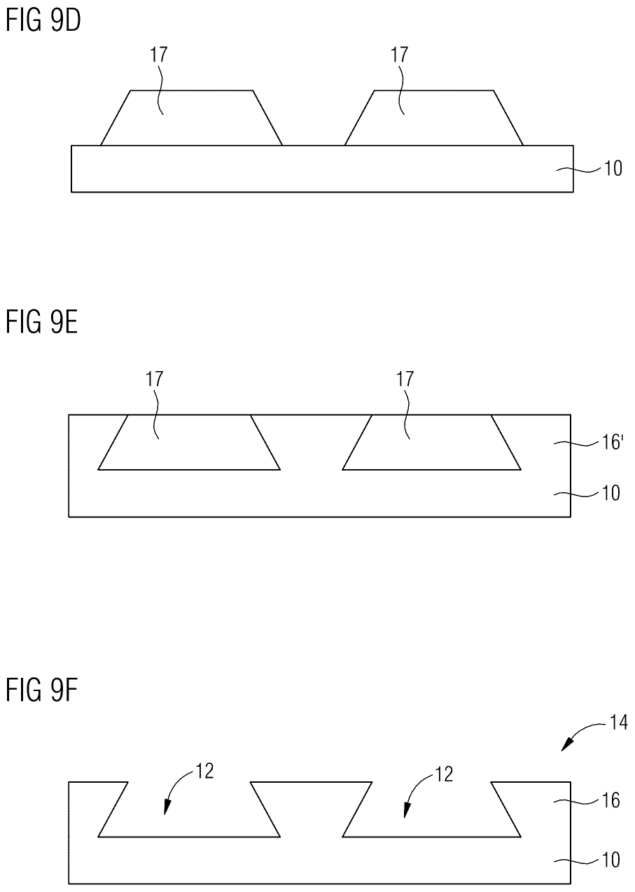

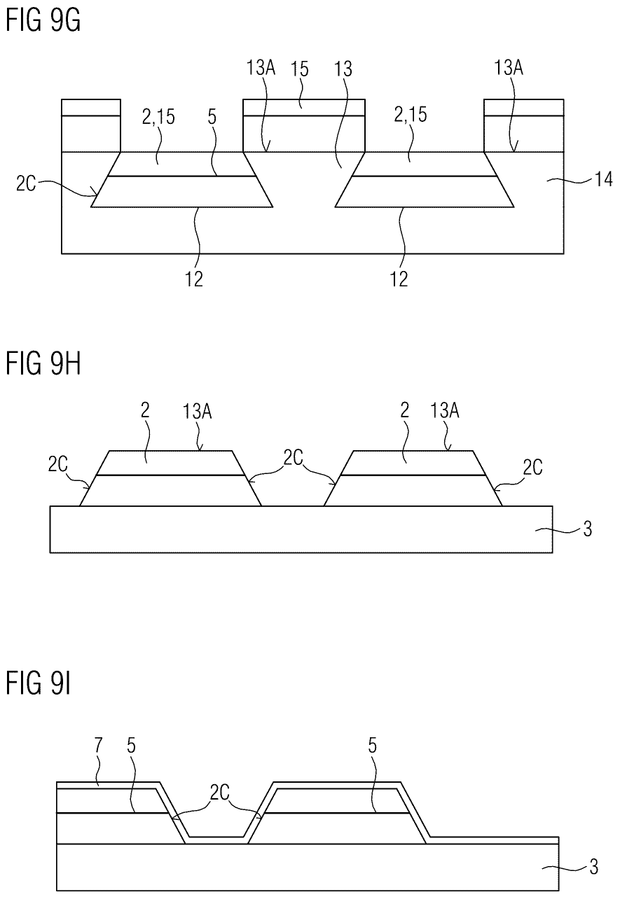

In connection with FIGS. 9A to 9I, a forth exemplary embodiment of a manufacturing method for producing an optoelectronic semiconductor device as described in connection with FIG. 1, for example, is explained in more detail.

Starting with FIG. 9A, a growth substrate layer 10 is provided, which comprises or consists of a semiconductor material, for example GaAs.

Continuing with FIG. 9B, a resist mask 11 is provided on the growth substrate layer 10 in areas where a patterned layer 16 is to be formed (see FIG. 9F). A shape of the resist mask 11 can be tuned with lithography conditions.

Continuing with FIG. 9C, a dielectric material 17, for example SiO2, is deposited on the growth substrate layer 10 around the resist mask 11. The material 17 may cover upper and side surfaces 11A, 11C of the resist mask 11. The material 17 may be deposited by a sputtering process or any low temperature process which does not lead to a damage of the resist mask 11.

Continuing with FIG. 9D, the resist mask 11 is removed, which is preceded by either removing the dielectric material 17 on the upper surface 11A of the resist mask 11 together with the resist mask 11 by a lift-off technique or by chemical mechanical polishing as described in connection with FIG. 8D and resist stripping.

Continuing with FIG. 9E, material 16′ of a patterned layer 16 (see FIG. 9F) is deposited on the growth substrate layer 10 in areas where the resist mask 11 (see FIG. 9C) has been removed. The deposition process may be an epitaxial growth process with controlled conditions to avoid parasitic growth on the dielectric material 17. The material 16′ of the patterned layer 16 may be a semiconductor material like GaAs.

Continuing with FIG. 9F, the dielectric material 17 is removed, wherein openings 12 are formed. The removal process may be an etching process. The growth substrate layer 10 with the patterned layer 16 constitutes a patterned growth substrate 14.

Continuing with FIG. 9G, a semiconductor layer sequence 15 is grown on the patterned growth substrate 14 such that the semiconductor layer sequence 15 is arranged in the openings 12, wherein the semiconductor layer sequence 15 in the openings 12 in each case forms a semiconductor layer stack 2 including an active region 5 and having one or more side surfaces 2C.

While parasitic growth occurs in each case on main surfaces 13A of the projecting portions 13, the growth conditions can be controlled in such a way that growth on edges of the main surfaces 13A is prevented.

Continuing with FIG. 9H, the parasitic growth portions on the main surfaces 13A of the projecting portions 13 are removed by chemical-mechanical polishing, for example. And parts of the patterned growth substrate 14 which cover the one or more side surfaces 2C of the semiconductor layer stacks 2 are removed. Especially, the projecting portions 13 are removed in this step. The removal process is an etching process, for example. After the removal process, the side surfaces 2C may undergo a cleaning process in order to reduce defects. The semiconductor layer stacks 2 produced in this way are arranged on a common carrier 3, which is a part of the patterned growth substrate 14, and are laterally spaced from each other by interspaces originating from the removed parts of the patterned growth substrate 14.

Continuing with FIG. 9I, a regrowth semiconductor layer 7 is deposited or grown on the side surfaces 2C of the semiconductor layer stacks 2, wherein the regrowth semiconductor layer 7 in each case covers the active regions 5 at the side surfaces 2C.

In addition, the method may have any of the features, characteristics and advantages mentioned in connection with the further exemplary embodiments.

The invention is not limited to these embodiments by the description based on the embodiments. Rather, the invention includes any new feature and any combination of features, which includes in particular any combination of features in the patent claims, even if this feature or this combination itself is not explicitly indicated in the patent claims or embodiments.

1.-16. (canceled)

17. An optoelectronic semiconductor device comprising:
at least one semiconductor layer stack comprising an active region and one or more side surfaces, wherein the active region extends to the one or more side surfaces; and
a regrowth semiconductor layer covering the active region at the one or more side surfaces,
wherein the at least one semiconductor layer stack is free of etching traces at the one or more side surfaces.

18. The optoelectronic semiconductor device according to claim 17, wherein the regrowth semiconductor layer covers every side surface at least for the most part.

19. The optoelectronic semiconductor device according to claim 17,
wherein the regrowth semiconductor layer extends from the one or more side surfaces to a main surface of the at least one semiconductor layer stack, and
wherein the main surface is arranged obliquely to every side surface.

20. The optoelectronic semiconductor device according to claim 19,
wherein the regrowth semiconductor layer comprises an opening at the main surface, and
wherein an electric contact layer is arranged in the opening and electrically contacts the at least one semiconductor layer stack.

21. The optoelectronic semiconductor device according to claim 17, wherein a semiconductor material system of the at least one semiconductor layer stack and/or the regrowth semiconductor layer is InGaAlP or AlInGaAsP.

22. The optoelectronic semiconductor device according to claim 17,
wherein the at least one semiconductor layer stack has a cross section similar to an acute trapezoid, and
wherein values of each acute angle range between 15° and 60°.

23. The optoelectronic semiconductor device according to claim 17, wherein the optoelectronic semiconductor device is a MicroLed.

24. A manufacturing method for producing the optoelectronic semiconductor device according to claim 17, the method comprising:
providing a patterned growth substrate comprising at least one opening;
growing a semiconductor layer sequence on the patterned growth substrate such that the semiconductor layer sequence is arranged in the at least one opening, wherein the semiconductor layer sequence in the at least one opening forms the at least one semiconductor layer stack;
removing parts of the patterned growth substrate which cover the one or more side surfaces of the at least one semiconductor layer stack; and
depositing the regrowth semiconductor layer on the one or more side surfaces of the at least one semiconductor layer stack, wherein the regrowth semiconductor layer covers the active region at the one or more side surfaces,
wherein the method is performed in the recited order.

25. The manufacturing method according to claim 24, wherein the at least one semiconductor layer stack is formed with a height lower than a depth of the at least one opening.

26. The manufacturing method according to claim 24, wherein removing parts of the patterned growth substrate includes an etching process.

27. The manufacturing method according to claim 24, wherein providing the patterned growth substrate includes providing a growth substrate layer and removing material from the growth substrate layer to form the at least one opening of the patterned growth substrate, wherein the growth substrate layer comprises a semiconductor material.

28. The manufacturing method according to claim 24, wherein providing the patterned growth substrate includes providing a growth substrate layer, which comprises a semiconductor material, and forming a patterned layer on the growth substrate layer, wherein the patterned layer comprises the at least one opening of the patterned growth substrate.

29. The manufacturing method according to claim 28, wherein the patterned layer comprises a dielectric material.

30. The manufacturing method according to claim 29, wherein forming the patterned layer includes:
providing a resist mask on the growth substrate layer in areas where the at least one opening is to be formed,
depositing material of the patterned layer on the growth substrate layer around the resist mask, and
removing the resist mask, wherein the at least one opening is formed.

31. The manufacturing method according to claim 28, wherein the patterned layer comprises a semiconductor material.

32. The manufacturing method according to claim 31, wherein forming the patterned layer includes:
providing a resist mask on the growth substrate layer in areas where the patterned layer is to be formed,
depositing a dielectric material on the growth substrate layer around the resist mask, removing the resist mask,
depositing material of the patterned layer on the growth substrate layer in areas where the resist mask has been removed, and
removing the dielectric material, wherein the at least one opening is formed.

33. An optoelectronic semiconductor device comprising:
at least two semiconductor layer stacks comprising in each case an active region and in each case one or more side surfaces, wherein active regions extend to the one or more side surfaces; and
a regrowth semiconductor layer covering the respective active region at the one or more side surfaces and extending continuously between the at least two semiconductor stacks,
wherein the regrowth semiconductor layer extends in each case from the one or more side surfaces to a main surface of the respective semiconductor layer stack, wherein the main surface is arranged obliquely to every side surface, and
wherein the at least two semiconductor layer stacks are free of etching traces at the one or more side surfaces.
